(19) United States
(12) Patent Application Publication
(10) Pub. No.: US 2007/0018218 A1
(43) Pub. Date: Jan. 25, 2007

(54) Fin field effect transistor memory cell, fin field effect transistor memory cell arrangement and method for producing the fin field effect transistor memory cell

(76) Inventors: Johannes Kretz, Dresden (DE); Franz Kreupl, Muenchen (DE); Michael Specht, Muenchen (DE); Gernot Steinlesberger, Muenchen (DE)

Correspondence Address: SLATER & MATSIL LLP, 17950 PRESTON ROAD, SUITE 1000, DALLAS, TX, 75252, US

(21) Appl. No.: 11/455,907

(22) Filed: Jun. 19, 2006

Related U.S. Application Data
(63) Continuation of application No. PCT/DE04/02739, filed on Dec. 14, 2004.

(30) Foreign Application Priority Data
Dec. 19, 2003 (DE) 103 59 889.8
May 11, 2004 (DE) 10 2004 023 301.2

(51) Int. Cl. H01L 29/94

(52) U.S. Cl. 257/296

(57) ABSTRACT

The invention relates to a bridge field-effect transistor storage cell comprising first and second source/drain areas and a channel area arranged therebetween, which are formed in a semiconductor bridge. The inventive storage cell also comprises a charge-coupled layer that is disposed at least partially on the semiconductor bridge and a metal conductive gate area on at least one part of the charge-coupled layer that is arranged in such a way that electric charge carriers are selectively introducible or removable by applying a predetermined electric voltage to the bridge field-effect transistor storage cell.

This application is a continuation of co-pending International Application No. PCT/DE2004/002739, filed Dec. 14, 2004, which designated the United States and was not published in English, and which is based on German Application No. 103 59 889.8, filed Dec. 19, 2003 and German Application No. 10 2004 023 301.2, filed May 11, 2004, all of which applications are incorporated herein by reference.

### TECHNICAL FIELD

The invention relates to a fin field effect transistor memory cell, a fin field effect transistor memory cell arrangement and a method for producing the fin field effect transistor memory cell.

### BACKGROUND

In view of the rapid development in computer technology, there is a need for high-density, low-power and nonvolatile memories, in particular for mobile applications in the area of data storage.

The prior art discloses a floating gate memory, in which an electrically conductive floating gate region is arranged above a gate insulating layer of a field effect transistor integrated in a substrate, into which floating gate region electrical charge carriers can be permanently introduced by means of Fowler-Nordheim tunneling. On account of the field effect, the value of the threshold voltage of such a transistor is dependent on whether or not charge carriers are stored in the floating gate. Consequently, an item of memory information can be coded in the presence or absence of electrical charge carriers in the floating gate layer.

However, introducing electrical charge carriers into a floating gate requires a high voltage of typically 15 V to 20 V. This may lead to damage to sensitive integrated components and is unattractive, moreover, for energy-saving (e.g., low-power applications) or mobile applications (e.g., mobile radio telephones, personal digital assistant, PDA).

In the case of an NROM memory (“nitrided read only memory”), a silicon nitride trapping layer is used as gate insulating layer of a field effect transistor, it being possible for charge carriers to be permanently introduced into the silicon nitride layer as charge storage layer by means of channel hot electron injection (tunneling of hot electrons). Typical programming voltages are approximately 9 V in this case, and write times of 150 ns are achieved at an individual cell.

The paper by Eitan, et al., (2000), “NROM: A Novel Localized Trapping, 2-Bit Nonvolatile Memory Cell” IEEE Electron Device Letters 21(11):543-545 discloses an NROM memory cell in which two bits of memory information can be stored in one transistor.

Such an NROM memory cell has the disadvantage of a high power consumption, however. Furthermore, the scalability of NROM memory cells is poor on account of short channel effects, such as the “punch through” effect, which occurs in particular at a channel length of typically less than 200 nm. Moreover, the read current is very small in the case of a small width of transistors of NROM memory cells. This is also an obstacle to continued scaling.

There is a need for high-density data memories having storage densities of preferably at least 1 Gbit/cm². Memory cell arrangements known from the prior art include a NAND arrangement having planar floating gate memory cells or so-called “virtual ground arrays” having NROM cells for storing two bits of information per memory cell. Storage capacities of approximately 1 Gbit can be achieved with these memory cell arrangements. However, for technological reasons a continued increase in the storage density is difficult on account of the poor scalability of these memory cell arrangements.

German Patent Application 102 20 923 A1 describes nonvolatile fin field effect transistor memory cells in which the material of the gate electrodes is present on the two sidewalls of the fins. The gate electrodes are made of metal or polysilicon.

The paper by G. Raghavan, et al., (“Raghavan”) Polycrystalline Carbon: A Novel Material for Gate Electrodes in MOS Technology, Japanese Journal of Applied Physics, Vol. 32, pages 380 to 383, 1993 describes a method for applying a polycarbon layer to a planar oxidized silicon substrate by means of a deposition method using methane as hydrocarbon precursor material. Furthermore, Raghavan discloses that the polycarbon layer can be used as gate material for a planar MOS field effect transistor.

U.S. Pat. No. 6,234,559 B1 discloses a planar field effect transistor in which the gate insulating layer has a carbon layer covering the gate electrode.

Furthermore, German Patent Application 198 56 294 A1 describes a planar chemical field effect transistor having a source region and drain region arranged on a semiconductor substrate, the source region and drain region being connected to one another by means of a conductive channel. The gate electrode of the planar chemical field effect transistor is formed by a carbon electrode. In this field effect transistor, after the immobilization of an ion-selective membrane on the gate electrode, it is possible, for example, to change the activity of ions on account of the resulting change in the gate surface potential.

U.S. Pat. No. 6,653,195 B1 describes a nonvolatile memory cell arrangement having a carbon layer as an electrode.

U.S. Patent Application Serial No. 2001/0052615 A1 and German Patent Application 103 16 892 A1 describe further nonvolatile memory cell arrangements having planar MOS field effect transistors and a layer respectively provided therein for nonvolatile storage of electrical charge carriers.

### SUMMARY OF THE INVENTION

The invention is based on the problem of providing a memory cell that can continue to be scaled even towards small dimensions.

The problem is solved by means of the fin field effect transistor memory cell, by means of a fin field effect transistor memory cell arrangement and by means of a method for producing a fin field effect transistor memory cell having the features in accordance with the independent patent claims.

The fin field effect transistor memory cell according to the invention contains a first and a second source/drain region and a channel region arranged in between, which source/drain and channel regions are formed in a semiconductor fin. A charge storage layer is furthermore provided, which is arranged at least partly on the semiconductor fin. The fin field effect transistor memory cell contains a metallically conductive gate region and at least one portion of the charge storage layer, the charge storage layer being set up in such a way that electrical charge carriers can be selectively introduced into the charge storage layer or be removed therefrom by means of applying predeterminable electrical potentials to the fin field effect transistor memory cell.

The fin field effect transistor memory cell arrangement according to the invention contains a plurality of fin field effect transistor memory cells having the features described above.

In the case of the method according to the invention for producing a fin field effect transistor memory cell, a first and a second source/drain region and a channel region arranged in between are formed in a semiconductor fin. Furthermore, a charge storage layer is formed at least partly on the semiconductor fin. A metallically conductive gate region is formed on at least one portion of the charge storage layer. The charge storage layer is set up in such a way that electrical charge carriers can be selectively introduced into the charge storage layer or be removed therefrom by means of applying predeterminable electrical potentials to the fin field effect transistor memory cell.

One basic idea of the invention is to be seen in the fact that the gate region of a fin field effect transistor memory cell (or the word line region of a fin field effect transistor memory cell arrangement) is formed from a metallically conductive material, that is to say from a material having an electrical conductivity which is characteristic of a metallic material. In other words, by way of example, metallic material, doped polycrystalline silicon material or carbon-containing material is introduced between adjacent semiconductor fins. To put it another way, this means that the metallically conductive material is preferably arranged at least partly on the sidewalls of the semiconductor fins.

The provision of gate region or word line made of a metallically conductive material leads to a low-impedance control of the memory cell and brings about an improved erasure performance, particularly if the material used is polycrystalline silicon provided with a dopant of the p conduction type, or a metal having a work function of preferably greater than 4.1 eV. The improved erasure performance results from a particularly advantageous potential profile between channel region, charge storage layer (e.g., provided as an ONO layer sequence) and gate region in a realization made of a metallically conductive material.

With the fin field effect transistor memory cell according to the invention, in the case of a “virtual ground array” architecture, the high storage density of, for example, 8 Gbit/cm² or more is combined with a high read-out rate.

In the case of the fin field effect transistor memory cell according to the invention, a high read-out rate is made possible in conjunction with high aspect ratios of the semiconductor fins, and this is accompanied by a good erasure performance. The read-out rates are better than in conventional NAND memories. An aspect ratio is understood to mean the ratio of height to width of the region between adjacent fins of a memory cell arrangement. Such a distance may be of the order of magnitude of 10 nm and the height of a fin may be 50 nm, by way of example.

Alternate embodiments of the invention are also disclosed herein.

The charge storage layer of the fin field effect transistor memory cell may be embodied as an electrically insulating charge storage layer. Memory cells having an electrically insulating charge storage layer enable lower programming voltages than those having a floating gate. An electronically insulating charge storage layer may also be referred to as a trapping layer since, clearly, electrical charge carriers are trapped in the electrically insulating layer.

According to the invention, the charge storage layer may have or comprise, by way of example, a silicon oxide/silicon nitride/silicon oxide layer sequence (ONO layer sequence), aluminum oxide, yttrium oxide, lanthanum oxide, hafnium oxide, amorphous silicon, tantalum oxide, titanium oxide, zirconium oxide, and/or an aluminate.

The gate region of the fin field effect transistor memory cell according to the invention or a word line region of the fin field effect transistor memory cell arrangement may consist of carbon material or comprise carbon material.

With the provision of the gate region made of a carbon-containing material, it is possible, even in the case of fins, which have a very small dimension or a very small distance between one another, to fill interspaces between adjacent fins in a positively locking manner with material of the gate region reliably and whilst avoiding air holes that impair the electrically driveability of the memory cell.

In the case of fin-FET memory cells it is difficult at very high storage densities, for example when adjacent fins are at a distance of 20 nm or less, to produce word line regions between the fins without air gaps and with good electrical conductivity.

With the use of conventional materials for gate regions or word line regions of a fin field effect transistor memory cell arrangement, it can happen that those electrodes in the narrow interspaces between adjacent semiconductor fins are not deposited with sufficiently good quality and sufficient conformity. By virtue of the invention forming fin field effect transistor memory cells having gate regions or word line regions that consist of carbon or comprise carbon, a material for the word line regions is created that can penetrate even into very narrow gaps or cavities having dimensions of 10 nm or less with homogeneous interface coverage and has a good electrical conductivity even for small thicknesses. The capability—achieved according to the invention—of homogeneously covering the semiconductor fins provided with the charge storage layer with the carbon-containing gate region has the effect that, when an electrical voltage is applied to the gate region, the electrical properties of the memory cell can be controlled or set exactly by means of the field effect. An entirely satisfactory functionality of the memory cell is thereby made possible even for high storage densities.

Consequently, a new possibility is afforded for creating a low-impedance, high-quality and miniaturized electrical drive line for a transistor memory cell with small distances of, for example, less than 30 nm between adjacent fins. Using carbon material for the gate regions or word line regions, even very narrow joints can be wetted with material. Moreover, the carbon material has a good electrical conductivity even for small thicknesses.

Experiments have shown that the carbon layer of the fin field effect transistor memory cell according to the invention has good adhesion properties in particular on a silicon oxide layer, thereby preventing such layers from being undesirably stripped from one another. The carbon layer may be patterned with high quality and a tenable outlay for example using an oxygen plasma or nitrogen plasma etching method. Furthermore, the deposition of silicon nitride material (e.g., as a covering or passivation layer) on the carbon-containing layer is technologically possible without any problems.

Doping material for increasing the electrical conductivity of the gate region may be introduced into the carbon material. By way of example, boron, aluminum, indium, phosphorus or arsenic may be used as doping material. Such doping material may be introduced or injected into the gate region for example during the production of the carbon-containing gate region, for example by virtue of an additional precursor having doping material being fed into the method chamber during a CVD deposition method (“chemical vapor deposition”). Such an additional precursor for providing boron doping material is, for example, diborane (B₂H₆).

The semiconductor fin may be formed from a bulk silicon substrate or from a silicon-on-insulator substrate. In other words, the memory cell according to the invention may be realized using bulk silicon technology or using SOI technology.

In the case of the fin field effect transistor memory cell, the gate region preferably has polycrystalline silicon or a metal. These materials are well suited as metallically conductive material.

In particular, the gate region may have doped polycrystalline silicon, it being possible for the doping atoms to be of the n conduction type or of the p conduction type.

The polycrystalline silicon preferably has doping material of the p conduction type, for example boron, aluminum or indium. Particularly if the polycrystalline silicon is p⁺-doped (that is to say has a very high p-type doping), a particularly effective erasure performance may be obtained on account of the advantageous energy band profile then obtained (cf. FIG. 9 and associated description). The same applies to metals having sufficiently high work function. In this case as in the case of a p-doped gate material, too, the gate current is reduced by a high barrier with respect to the top oxide, thus resulting in efficient erasure by the hole current from the substrate.

The gate region may have a metal having a work function that is sufficiently high in order that a gate current required for erasing the memory cell is kept small.

The gate region may have a metal having a work function of at least 4.1 electronvolts.

The fin field effect transistor memory cell arrangement according to the invention, having fin field effect transistor memory cells according to the invention, is described in more detail below. Refinements of the fin field effect transistor memory cell also apply to the fin field effect transistor memory cell arrangement, and vice versa.

The fin field effect transistor memory cells of the fin field effect transistor memory cell arrangement may be arranged essentially in matrix-type fashion.

Fin field effect transistor memory cells arranged along a first direction may have common word line regions, which are coupled to the gate regions of the assigned fin field effect transistor memory cells and are formed from the same material as the gate regions. Consequently, the gate regions and the word line regions of a row or column of fin field effect transistor memory cells of the memory cell arrangement may clearly comprise an integral and unary carbon structure.

The fin field effect transistor memory cell arrangement may be set up as a NAND memory cell arrangement. In this case, the fins may be arranged essentially in a manner running orthogonally with respect to the word line regions. The word line regions may be used as a mask for forming the source/drain regions of the fin field effect transistor memory cells. It is possible in a NAND architecture for a semiconductor fin clearly to be concomitantly used as part of the bit line. Preferably, however, vias are formed at a distance of a predetermined number (typically 8 or 16) of memory cells from a semiconductor fin, which vias are used to realize a coupling of the source/drain regions with metallic bit lines of a wiring plane.

The fin field effect transistor memory cell arrangement according to the invention may be set up in such a way that, by means of applying predeterminable electrical potentials so at least one gate region and to at least one portion of the source/drain regions, charge carriers can selectively be introduced into the charge storage layer of at least one selected fin field effect transistor memory cell by means of Fowler-Nordheim tunneling or be removed therefrom.

As an alternative to the NAND memory cell arrangement, the fin field effect transistor memory cell arrangement according to the invention may have at least one first bit line region and at least one second bit line region, the first source/drain region of a respective fin field effect transistor memory cell being coupled to an assigned first bit line region and the second source/drain region of a respective fin field effect transistor memory cell being coupled to an assigned second bit line region. By way of example, such bit line regions may be provided in a wiring plane above the gate regions or the word line regions, a memory cell, in a crossover region between a word line and a bit line, being driven by means of an assigned word line and being read or programmed by means of assigned bit lines.

The first and second bit line regions may be arranged essentially in a manner running in a second direction, which second direction is arranged obliquely with respect to the first direction. The semiconductor fin is preferably arranged essentially in a manner running orthogonally with respect to the word line or the gate regions coupled to one another. In this case, it is necessary to provide the bit line regions in a wiring plane arranged above the word line plane, for example, in a manner running obliquely with respect to the word lines, for example at an angle of 45°. The first and second bit line regions may run in rectilinear fashion or have a zig zag-like or sawtooth-shaped structure. If a bit line region is provided as a zig zag- or sawtooth-like structure that essentially runs along the second running direction obliquely with respect to the word line regions, it is possible to form bit line regions that are essentially of the same length and thus have an essentially identical non-reactive resistance and that can be used to drive source/drain regions of fin field effect transistor memory cells.

The semiconductor fins of the fin field effect transistor memory cells and the word line regions may be arranged in a manner running along a third direction and first and second bit line regions are arranged in a manner running along a fourth direction, which third direction is arranged perpendicular to the fourth direction.

The fin field effect transistor memory cell may be set up in such a way that, by means of applying predeterminable electrical potentials to at least one word line region and to at least one portion of the bit line regions, charge carriers can selectively be introduced into the charge storage layer of at least one selected fin field effect transistor memory cell by means of tunneling of hot charge carriers or be removed therefrom. By means of the tunneling of hot electrons or the tunneling of hot holes, electrical charge carriers can be permanently introduced into the charge storage layer with short writing times, the memory information being coded in these introduced electrical charge carriers.

The fin field effect transistor memory cell arrangement described may be set up for storing two bits of information in a fin field effect transistor memory cell by means of introducing charge carriers into the charge storage layer into a boundary region between the first source/drain region and the channel region and into a boundary region into the second source/drain region and the channel region of a respective fin field effect transistor memory cell. Consequently, the memory cell arrangement of the invention can be operated as a dual bit memory cell, a high-density semiconductor memory thereby being created.

The first and second bit line regions may be embodied as virtual ground wirings.

The semiconductor fins of adjacent fin field effect transistors may be arranged at a distance of from 10 nm to 100 nm, preferably at most 30 nm, more preferably at most 20 nm, or at most 10 nm, from one another. It is possible even with very small distances between adjacent semiconductor fins to create a gate region having sufficient conformity and quality made from a carbon-containing material.

Furthermore, an electrically insulating covering layer that covers the word line regions at least in part may be provided. A silicon nitride covering layer has particularly good material properties in combination with a carbon-containing word line region, in particular stripping of such a covering layer is reliably avoided.

The covering layer may extend into cavities between semiconductor fins covered with the word line region. Consequently, the covering layer may be concomitantly used as a spacer or decoupling element between adjacent fins, thereby avoiding undesirable crosstalk between adjacent memory cells. A mechanical decoupling of adjacent memory cells is realized by means of the regions of the covering layer between adjacent semiconductor fins.

The method according to the invention for producing a fin field effect transistor memory cell is described in more detail below. Refinements of the fin field effect transistor memory cell or of the fin field effect transistor memory cell arrangement also apply to the method for producing a fin field effect transistor memory cell, and vice versa.

The carbon material of the gate region may be formed using a chemical vapor deposition (CVD) method. By way of example, methane (CH₄), acetylene (C₂H₂) or ethene (C₂H₄) may be used for forming the carbon material.

As a carbon source for forming the carbon material, methane gas is particularly well suited as a precursor in a CVD method, since this small molecule can penetrate particularly well into the narrow interspaces between adjacent semiconductor fins. Using methane gas a precursor for forming the carbon-containing gate region, air holes are avoided particularly reliably.

A substance containing doping material may be supplied during the formation of the carbon material, which doping material is set up in such a way that it increases the electrical conductivity of the gate region. By way of example, it is possible to supply diborane as a boron source for doping the carbon-containing material of the gate region, as a result of which a very homogeneous boron doping is achieved in the carbon material.

After the formation of the carbon material, the latter may be subjected to a heat treatment method step. By way of example, the carbon material formed may be treated for approximately two minutes under an argon atmosphere and at a temperature of typically from 1000 to 1100° C., preferably 1050° C. By means of such a heat treatment method step, the non-reactive resistance of the carbon layer can typically be reduced by a factor of two or more. Therefore, the material property of the gate region can be additionally improved by means of the heat treatment method step.

By way of example, the following parameters may be used for a method for producing the carbon-containing layer in the context of a CVD method. Hydrogen gas having a pressure of between 10⁻⁴ bar and 10⁻² bar, preferably 10⁻³ bar, may be used as a preconditioning gas. Furthermore, it is possible to supply methane as a carbon source for forming the carbon-containing layer at a pressure of between 0.2 bar and 0.7 bar, preferably 0.6 bar. The operating temperature during the production method is typically between 950° C. and 1000° C. The thickness of the carbon layer can be set by means of predetermining the processing duration.

In order to produce the fin field effect transistor memory cell according to the invention, energy may be supplied by means of an electromagnetic radiation source. As an alternative to the conventional heating of a CVD apparatus, the method chamber can thus be heated to 800° C. by means of a clearly photonic heating, that is to say an electromagnetic radiation source as energy source. The carbon layer is then produced at a pressure of between 10⁻³ bar and 10⁻² bar, preferably 3.3 10⁻³ bar, hydrogen and between 10⁻³ bar and 10⁻¹ bar, preferably 10⁻² bar, methane.

The carbon material may be deposited and patterned using a plasma etching method for forming the gate region. A hydrogen plasma or oxygen plasma etching method is preferably used for the plasma etching method.

### BRIEF DESCRIPTION OF THE DRAWINGS

Exemplary embodiments of the invention are illustrated in the figures and are explained in more detail below. In the figures:

FIG. 1 shows a cross-sectional view of a fin field effect transistor memory cell arrangement in accordance with a first exemplary embodiment of the invention;

FIG. 2 shows the fin field effect transistor memory cell arrangement shown in FIG. 1 in an operating state in which electrical charge carriers are introduced into the charge storage layer;

FIGS. 3A to 3D show layer sequences at different points in time during a method for producing the fin field effect transistor memory cell arrangement from FIG. 1;

FIG. 4 shows a layout plan view of a fin field effect transistor memory cell arrangement in accordance with the first exemplary embodiment of the invention;

FIG. 5 shows a layout plan view of a fin field effect transistor memory cell arrangement in accordance with the second exemplary embodiment of the invention;

FIG. 6 shows a fin field effect transistor memory cell arrangement in accordance with a third exemplary embodiment of the invention, with sawtooth-shaped bit lines;

FIG. 7 shows a cross-sectional view of a fin field effect transistor memory cell arrangement in accordance with a fourth exemplary embodiment of the invention;

FIG. 8 shows a layout plan view of a fin field effect transistor memory cell arrangement in accordance with the fourth exemplary embodiment of the invention; and

FIG. 9 shows an energy band profile between channel region, ONO charge storage layer and metallically conductive gate region of a fin field effect transistor memory cell in accordance with one exemplary embodiment of the invention.

Identical or similar components in different figures are provided with the same reference numerals.

The illustrations in the figures are schematic and are not to scale.

The following list of reference symbols can be used in conjunction with the figures:
100 Fin field effect transistor memory cell
101 Silicon substrate
102 Buried silicon oxide layer
103 First silicon fin
104 Second silicon fin
105 Channel region
106 ONO charge storage layer sequence
107 Carbon word line
108 Silicon nitride covering layer
109 Word line course direction
110 First fin field effect transistor memory
111 Second fin field effect transistor
200 Electrical charge carriers
300 Layer sequence
301 Silicon layer
302 SOI substrate
310 Layer sequence
311 First silicon fin
312 Second silicon fin
320 Layer sequence
321 Carbon layer
330 Layer sequence
400 Fin field effect transistor memory cell
401 First source/drain region arrangement
402 Second source/drain region
403 Fin course direction
404 n-doped regions
500 Fin field effect transistor memory cell arrangement
501 First charge storage region
502 Second charge storage region
600 Fin field effect transistor memory cell arrangement
601 First sawtooth bit line
602 Second sawtooth bit line
700 Fin field effect transistor memory cell
701 TEOS layer memory cell
702 Insulation layer
703 Bit line
800 Layout plan view
801 Spacer
900 Energy band profile
901 Channel region
902 p⁺-doped polysilicon gate region
903 ONO charge storage layer
904 First silicon oxide layer
905 Silicon nitride layer
906 Second silicon oxide layer arrangement

### DETAILED DESCRIPTION OF ILLUSTRATIVE EMBODIMENTS

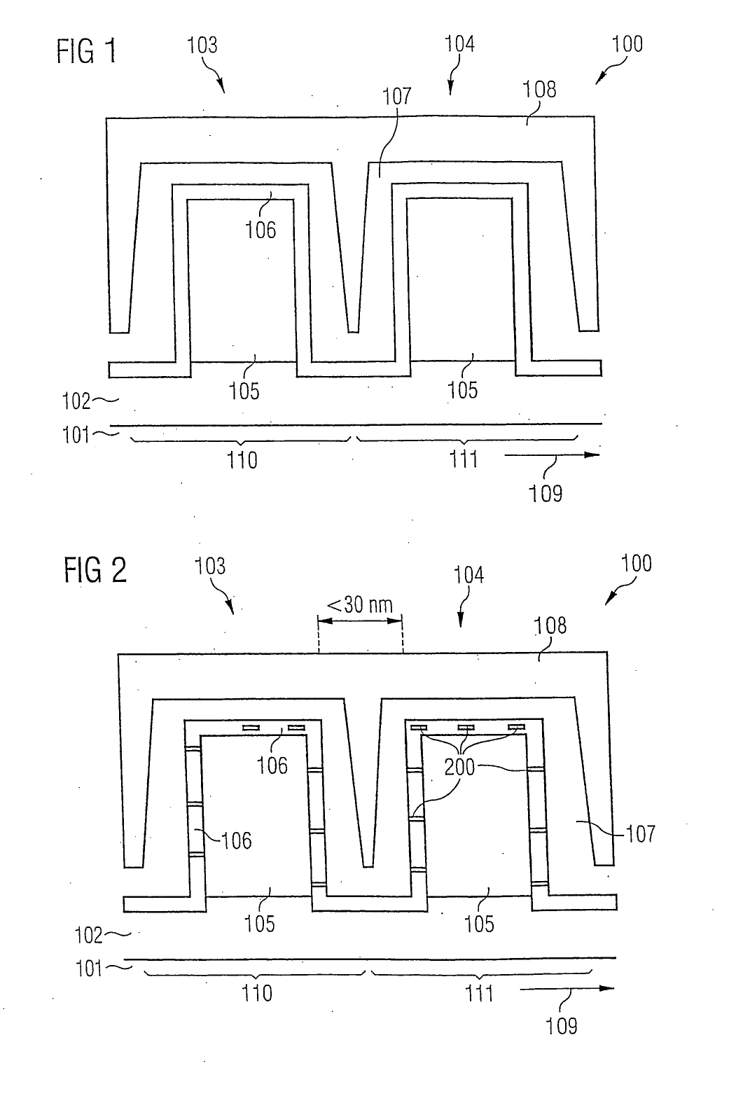

Even though the gate region is formed from material having carbon in the exemplary embodiments of FIG. 1 to FIG. 8, all these exemplary embodiments can alternatively be realized with a different metallically conductive material as the gate region, in particular with polysilicon material, preferably with p-doped polysilicon material, and more preferably with p⁺-doped polysilicon material.

A description is given below of the functionality of the fin field effect transistor memory cell arrangement 100 in accordance with a first exemplary embodiment of the invention as shown in FIG. 1.

FIG. 1 shows a first fin field effect transistor memory cell 110 and a second fin field effect transistor memory cell 111.

The fin field effect transistor memory cell arrangement 100 is formed on a silicon substrate 101. A buried silicon oxide layer 102 is formed on the silicon substrate 101. In other words, the fin field effect transistor memory cell arrangement 100 is formed proceeding from an SOI substrate having the silicon substrate 101, the buried silicon oxide layer 102 and a silicon layer arranged on the buried silicon oxide layer 102, only the regions 105 of which silicon layer are present in FIG. 1 on account of the processing for producing the memory cell arrangement 100.

Each of the fin field effect transistor memory cells 110, 111 has a first and second source/drain region, which cannot be discerned in FIG. 1. A channel region 105 is shown in the cross-sectional view of FIG. 1. The first and second source/drain regions are clearly provided as n-doped regions of the silicon layer of the SOI substrate in a direction perpendicular to the paper plane of FIG. 1 above the paper plane and below the paper plane, respectively.

Each channel region 105 forms, together with the two assigned source/drain regions, a silicon fin arranged in a manner running perpendicular to the paper plane of FIG. 1. An ONO charge storage layer sequence 106 is formed on each silicon fin. The ONO charge storage layer sequence 106 comprises two silicon oxide layers and—arranged between the latter—a silicon nitride layer as a trapping layer for the introduction of electrical charge carriers.

A carbon word line 107 is applied on the charge blocking layer 106. Clearly, those sections of the carbon word line 107 that cover the region of the charge storage layer 106 that is arranged on a respective channel region 105 form the gate region of the associated fin field effect transistor memory cell 110 and 111, respectively. The distance between adjacent silicon fins is in the region of 30 nm or less, as shown in FIG. 2. Despite this very small distance between adjacent semiconductor fins, the carbon layer 107 can be deposited on the charge storage layer 106 very conformally and in a manner avoiding air holes.

The carbon word line 107 is coated with a silicon nitride covering layer 108 extending into regions between the fins. Silicon nitride has very good adhesion properties on carbon and brings about a mechanical decoupling between adjacent fin field effect transistor memory cells 110, 111 on account of the post-like spacers in the trenches covered with carbon material between adjacent fins. With very narrow distances between the fins, the silicon nitride material no longer penetrates into the trench since the carbon material completely fills the trench.

FIG. 2 shows the fin field effect transistor memory cell arrangement in an operating state in which electrical charge carriers 200, namely electrons, have been introduced into the silicon oxide trapping layer of the ONO charge storage layer sequence 106. The information stored in the memory cells 110, 111 is coded in these introduced electrons.

In a configuration of the fin field effect transistor memory cell arrangement in NAND architecture, the electrical charge carriers 200 are introduced into the ONO charge storage layer sequence 106 by means of Fowler-Nordheim tunneling. In a configuration of the fin field effect transistor memory cell arrangement 100 as a dual bit memory cell arrangement, the electrical charge carriers 200 are introduced into the ONO charge storage layer sequence 106 by means of tunneling of hot charge carriers.

The electrical charge carriers 200 in the ONO charge storage layer sequence 106 effectively have the effect like a gate voltage as can be applied to a carbon word line 107. This is because the electrical charge carriers 200 influence the electrical conductivity of the channel region 105 in a similar manner to an electrical voltage applied to the gate region via word line 107. Consequently, given a fixed voltage between the two source/drain regions of a respective fin field effect transistor memory cell 110, 111, the value of the electric current flow between the two source/drain regions is dependent on whether or not charge carriers have been introduced in the ONO charge storage layer sequence 106. Consequently, the storage information of the respective fin field effect transistor memory cell 110, 111 is coded in the electrical charge carriers 200.

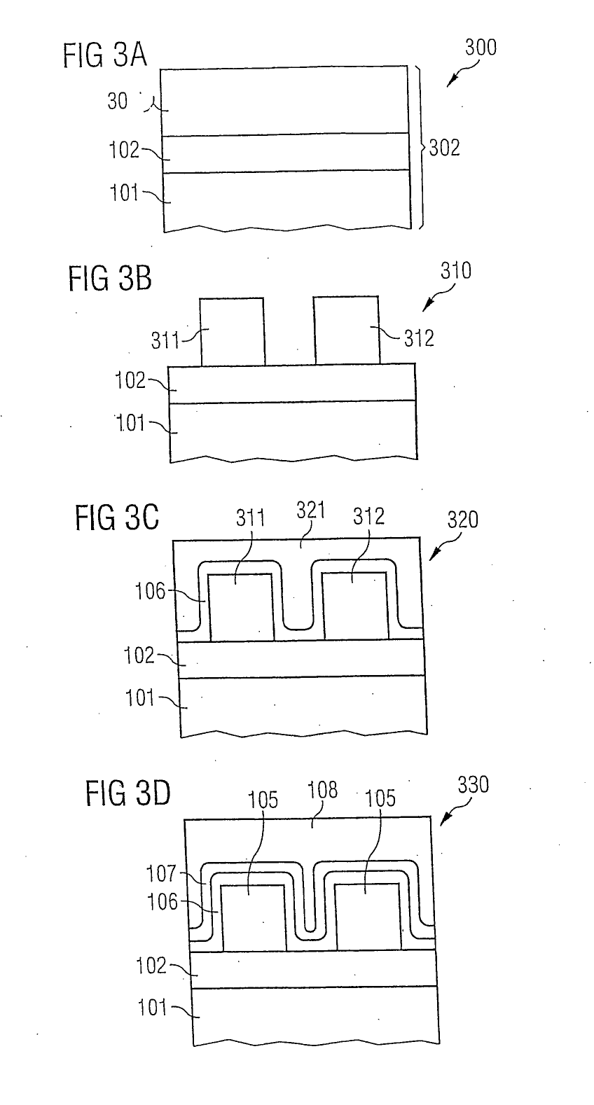

A description is given below, referring to FIG. 3A to FIG. 3D, of a method for producing the fin field effect transistor memory cell arrangement 100 shown in FIG. 1.

The field effect transistor memory cell arrangement 100 is formed proceeding from an SOI substrate 302 (“silicon on insulator”) composing silicon substrate 101, the buried silicon oxide layer 102 arranged thereon and silicon layer 301 arranged thereon. A bulk wafer with a suitable well doping may also be used as an alternative to an SOI wafer 302 as starting material.

In order to obtain the layer sequence 310 shown in FIG. 3B, the silicon layer 301 of the layer sequence 300 is patterned using a lithography and an etching method in such a way that first and second silicon fins 311, 312 are formed at a distance of less than 30 nm away from one another. For this purpose, firstly a photoresist layer (not shown) is applied to the silicon layer 301 and patterned using an etching method. After the regions between adjacent fins 311, 312 have been etched, the photoresist layer is removed from the surface of the layer sequence (“stripping”).

In order to obtain the layer sequence 320 shown in FIG. 3C, an ONO charge storage layer sequence 106 is applied to the silicon fins 311, 312. For this purpose, firstly a first silicon oxide partial layer is deposited, a silicon nitride partial layer is deposited on the first silicon oxide partial layer, and a second silicon oxide partial layer is deposited on the silicon nitride partial layer. The two silicon oxide partial layers and the silicon nitride partial layer arranged in between together form the ONO charge storage layer sequence 106. A carbon layer 321 for forming gate or word line regions is deposited on the ONO charge storage layer sequence 106 using a CVD method (“chemical vapor deposition”).

In order to obtain the layer sequence 330 shown in FIG. 3D, the carbon layer 321 is patterned using a lithography and a plasma etching method (oxygen plasma etch) in such a way that the carbon word line 107 is thereby formed. In a further method step, the carbon word lines 107 are used as an implantation mask during the introduction of doping material of the n conduction type into those regions of the silicon fins 311, 312 that form first and second source/drain regions of the fin field effect transistor memory cells.

The layer sequence thus obtained is subsequently covered with a silicon nitride covering layer 108. A TEOS layer sequence (“tetraethyl orthosilicate”) may alternately be used as a covering layer.

In order to arrive at the fin field effect transistor memory cell arrangement 100 from the layer sequence 330 shown in FIG. 3D, the back end region is processed in processing planes above the covering layer 108, in particular metallization planes are formed (not shown). The way in which the back end region is formed depends on the configuration of the fin field effect transistor memory cell arrangement as a NAND memory cell arrangement or as a dual bit memory cell arrangement.

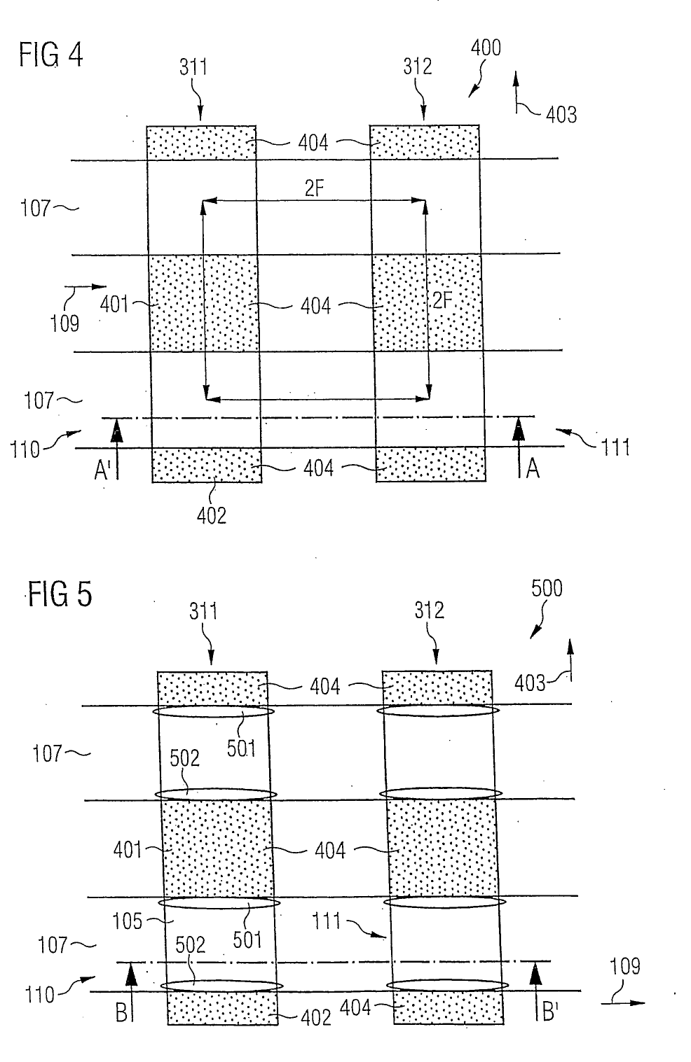

A description is given below, referring to FIG. 4, of a layout plan view of a fin field effect transistor memory cell arrangement 400 in accordance with a second exemplary embodiment of the invention. The fin field effect transistor memory cell arrangement 400 is embodied in NAND architecture. The cross-sectional view shown in FIG. 1 is taken along the line A-A′ shown in FIG. 4.

As shown in FIG. 4, the semiconductor fins 311, 312 run perpendicular to the carbon word lines 107. A fin field effect transistor memory cell is arranged in each crossover region between a silicon fin 311, 312 and a carbon word line 107. As shown in FIG. 4, the extent of a fin field effect transistor memory cell in the horizontal and vertical directions in accordance with FIG. 4 is 2 F in each case, where F represents the minimum feature size that can be achieved in a technology generation. Consequently, the fin field effect transistor memory cells of the invention are formed as memory cells having an area requirement of 4 F². The regions of the silicon fins 311, 312 that are free of a covering with a word line 107 are formed as n-doped regions. In particular, a first source/drain region 401 and second source/drain region 402 of the first fin field effect transistor memory cell 110 shown in FIG. 1 are illustrated.

The fin course direction 403 is orthogonal to the word line course direction 109.

FIG. 4 does not show the select transistors and the plane of the global bit lines, which typically make contact with the respective source/drain regions at a distance of eight to sixteen memory cells using vias. External control, programming or read voltages can be applied to such low-impedance bit lines. An information item of one bit can be stored in each field effect transistor memory cell of the memory cell arrangement 400.

A description is given below, referring to FIG. 5, of a fin field effect transistor memory cell arrangement 500 in accordance with the third exemplary embodiment of the invention. FIG. 5 shows a layout plan view of the memory cell arrangement 500. The cross-sectional view shown in FIG. 1 is taken along the line B-B′ shown in FIG. 5. In other words, the cross-sectional view from FIG. 1 is identical in the case of the memory cell arrangements shown in FIG. 4 and FIG. 5, whereas the interconnection architecture is different in the case of the memory cell arrangements 400 and 500, as emerges from FIG. 4 and FIG. 5.

The memory cell arrangement 500 is embodied as a dual bit memory cell arrangement in which an information item of two bits can be stored in each memory cell. On account of the embodiment of the memory cell arrangement 500 as a dual bit memory cell arrangement, it is necessary to make contact with the source/drain regions of the fin field effect transistor memory cells of the memory cell arrangement 500 by means of bit lines via which electrical control and read-out signals can be applied in accordance with a “virtual ground array” architecture. For this purpose, a plurality of bit lines arranged above the paper plane of FIG. 5 are formed, the bit lines being coupled to respective source/drain regions of the fin field effect transistor memory cell arrangement 500.

In order to form such bit lines, proceeding from FIG. 3D, the silicon nitride covering layer 108 is subjected to a lithography and an etching method, whereby bit line contacts are etched as passage holes and filled with titanium nitride and tungsten material. In a metallization plane arranged thereabove, the bit lines are formed by firstly depositing a whole-area metallization layer and patterning the latter using an additional lithography method and an additional etching method. The back end contact-making may subsequently be effected.

As shown schematically in FIG. 5, two bits of information can in each case be stored in each of the fin field effect transistor memory cells 110, 111 of the fin field effect transistor memory cell arrangement 500 in that, independently of one another, electrical charge carriers may or may not be introduced into a first charge storage region 501 and into a second charge storage region 502 of a respective memory cell. The first charge storage 501 is arranged in a boundary region between the first source/drain region 401 of a memory cell 110 and the channel region 105 of the memory cell. The second charge storage region 502 is arranged in a boundary region between the channel region 105 and the second source/drain region 402. By means of tunneling of hot electrons or holes, electrical charge carriers can be introduced independently of one another into each of the charge storage regions 501, 502. Since the value of a current flow between the source/drain regions of a respective memory cell depends on whether or not electrical charge carriers have been introduced into the first charge storage layer and/or the second charge storage layer, two bits of information can be stored per memory cell.

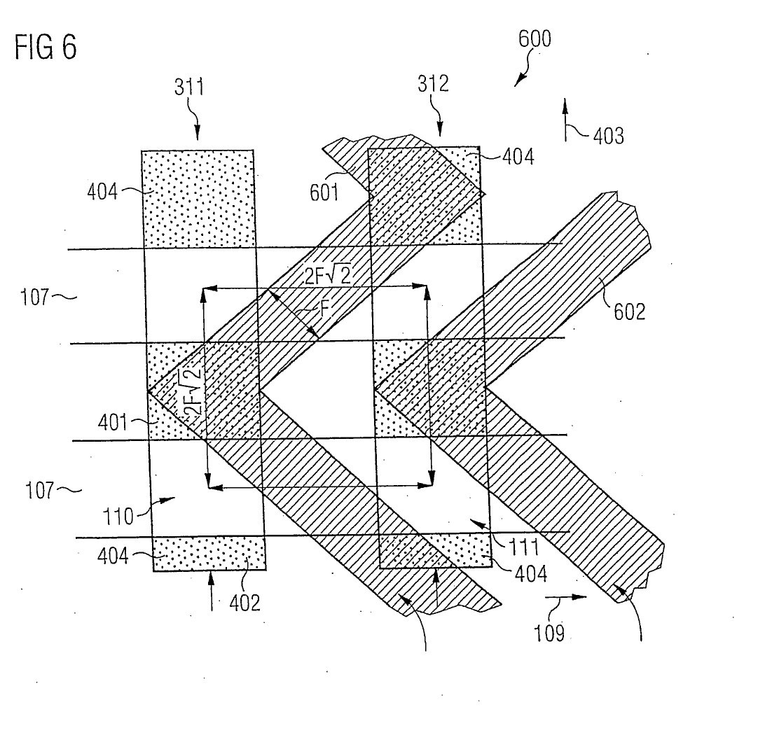

A description is given below, referring to FIG. 6, of a fin field effect transistor memory cell arrangement 600 in accordance with a third exemplary embodiment of the invention.

The memory cell arrangement 600 is embodied as a dual bit memory cell arrangement like the memory cell arrangement 500. In contrast to FIG. 5, the layout plan view of FIG. 6 shows how the bit lines for driving the source/drain regions of the fin field effect transistor memory cells are arranged.

Firstly, it should be noted that in the memory cell arrangement according to the invention, the course direction between word lines 109 and semiconductor fins 403 may run orthogonally with respect to one another. On the other hand, for driving a respective memory cell in dual bit operation it is necessary that the source/drain regions of the memory cell can be driven by means of bit lines. Since this requires crossover regions between the word lines 107 and the bit lines 601 and 602, respectively, the bit lines 601, 602 are arranged obliquely with respect to the word lines in accordance with the exemplary embodiment of FIG. 6. This may be realized (in a departure from the illustration shown in FIG. 6) by forming the bit lines for example at an angle of 45° with respect to the word lines in plan view. In accordance with the exemplary embodiment shown in FIG. 6, however, the bit lines 601, 602 are formed in sawtooth-shaped fashion or in zig zag fashion, in which case, in each crossover region between the bit lines 601, 602 and a source/drain region 401, 402, 404 vias are led down running perpendicular to the paper plane of FIG. 6 from the bit lines 601, 602 to the respective source/drain regions 404, whereby an electrical coupling is realized. The sawtooth-like structure of the bit lines has the advantage that all sawtooth bit lines of a memory cell arrangement having a multiplicity of memory cells are essentially formed with the same length, so that the non-reactive resistances of bit lines 601, 602 are approximately identical for all the bit lines.

The bit lines 601, 602 are formed in a single metal plane (bit line plane). The minimum feature size of the semiconductor memory depends on the extent of the bit lines. The dimension of a memory cell in the horizontal direction in accordance with FIG. 6 corresponds to 2 F\sqrt{2}. The bit lines 601, 602 are formed at an angle of 45° with respect to the word lines 107. The width of the word line 107 and the width of the semiconductor fins 311, 312 is in each case F\sqrt{2}. Consequently, the space requirement of an individual memory cell in accordance with the configuration of FIG. 6 is equal to 8 F². The method for producing the memory cell array in “virtual ground array” architecture as illustrated in FIG. 6 is less complicated on account of the only one bit line plane required.

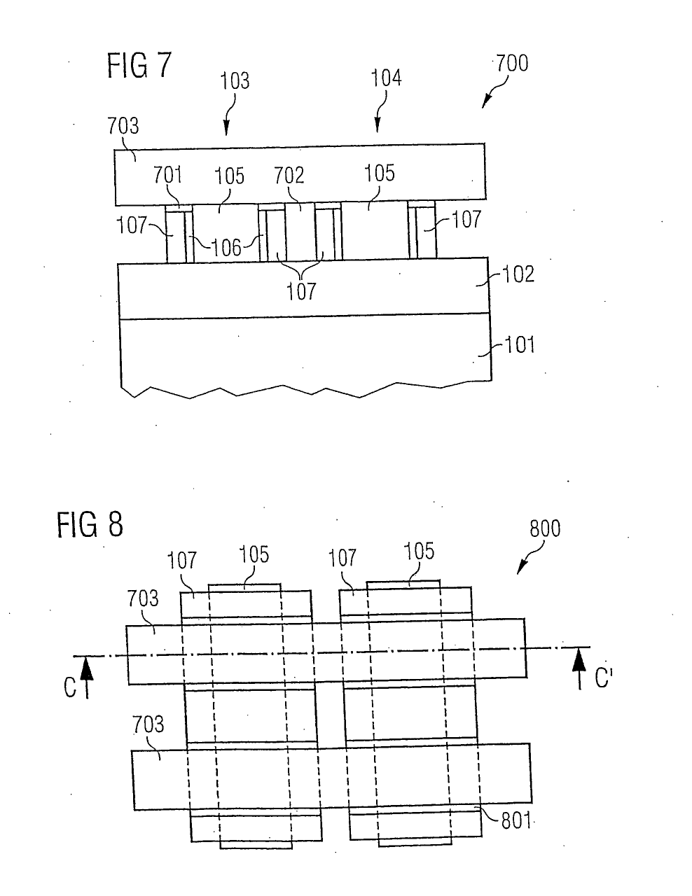

A description is given below, referring to FIG. 7, of a fin field effect transistor memory cell arrangement 700 in accordance with a fourth exemplary embodiment of the invention.

The fin field effect transistor memory cell arrangement 700 is embodied in dual bit architecture.

FIG. 8 shows a layout plan view 800 of the fin field effect transistor memory cell arrangement 700. The cross-sectional view shown in FIG. 7 is taken along the line C-C′ shown in FIG. 8.

The fin field effect transistor memory cell arrangement 700 differs from the fin field effect transistor memory cell arrangement 500 shown in FIG. 5 essentially by virtue of the fact that the word lines 107 are formed in a manner running parallel to the fins 105 and that the bit lines 703 are formed in a manner running perpendicular to the fins 105. The bit lines 703, which can be discerned in the cross-sectional view of FIG. 7, are electrically decoupled from the word lines 107 by means of a TEOS layer 701 (“tetraethyl orthosilicate”). Furthermore, an insulation layer 702 is formed between word lines 107. FIG. 8 furthermore shows a spacer 801.

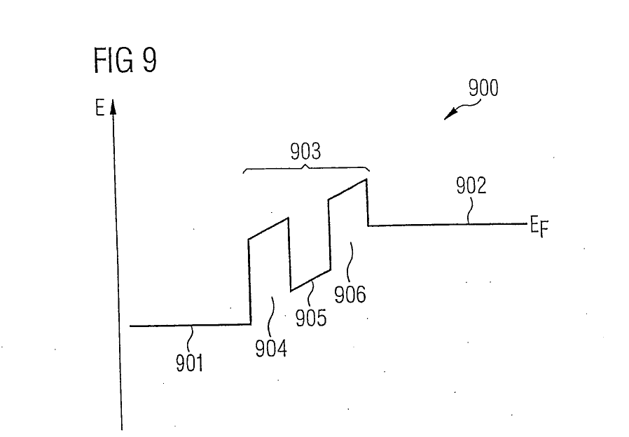

A description is given below, referring to FIG. 9, of an energy band profile between channel region, ONO charge storage layer and metallically conductive gate region of a fin field effect transistor memory cell in accordance with one exemplary embodiment of the invention.

The energy band profile 900 schematically shows the potential profile along a fin field effect transistor memory cell according to the invention in an operating state in which an erased voltage (e.g., 10 V) is applied. This leads to the potential profile shown in FIG. 9, in which the potential of a channel region 901 is reduced with respect to the potential of a metallically conductive p⁺-doped polysilicon gate region 902. An ONO layer sequence 903 as charge storage region is arranged between the channel region 901 and the polysilicon gate region 902. The ONO layer sequence contains a first silicon oxide layer 904 adjacent to the channel region 901, second silicon oxide layer 906 adjacent to the p⁺-doped polysilicon gate region 902, and a silicon nitride layer 905 between the two silicon oxide layers 904 and 906. Electrical charge carriers have been introduced in the silicon nitride layer 905 in a temporally earlier programming step. In the operating state with an applied erase voltage as shown in FIG. 9, the charge carriers are removed from silicon nitride layer 105 and carried away into the channel region 901. Since the polysilicon gate region 902 is p⁺-doped, this reliably prevents charge carriers from the gate region 902 from being undesirably introduced into the silicon nitride layer 905 during erasure. Consequently, on account of the use of a metallically conductive gate region 902 and in particular on account of the use of a p⁺-doped gate region 902, a particularly advantageous erasure performance is achieved by virtue of the reduction of the portion of the backflow of charge carriers from the gate region 902.

What is claimed is:

1. A memory cell comprising:
a semiconductor fin;
a first and a second source/drain region disposed in the semiconductor fin;
a channel region disposed in the semiconductor fin between the first and second source/drain regions;
a charge storage layer arranged at least partly over the semiconductor fin and at least partly over sidewalls of the semiconductor fin; and
a conductive gate region over at least a portion of the charge storage layer;
wherein the charge storage layer is arranged such that electrical charge carriers can be selectively introduced into the charge storage layer or be removed therefrom by applying electrical potentials to the fin field effect transistor memory cell.

2. The memory cell as claimed in claim 1, wherein the charge storage layer comprises a silicon oxide/silicon nitride/silicon oxide layer sequence; aluminum oxide; yttrium oxide; lanthanum oxide; hafnium oxide; amorphous silicon; tantalum oxide; titanium oxide; zirconium oxide; and/or aluminate.

3. The memory cell as claimed in claim 1, wherein the gate region consists of carbon material or comprises carbon material.

4. The memory cell as claimed in claim 3, wherein the carbon material contains doping material for increasing the electrical conductivity of the gate region.

5. The memory cell as claimed in claim 4, wherein the doping material comprises boron; aluminum; indium; phosphorus; and/or arsenic.

6. The memory cell as claimed in claim 1, wherein the semiconductor fin is formed from a bulk silicon substrate or a silicon-on-insulator substrate.

7. The memory cell as claimed in claim 1, wherein the gate region comprises polycrystalline silicon or a metal.

8. The memory cell as claimed in claim 7, wherein the gate region comprises doped polycrystalline silicon.

9. The memory cell as claimed in claim 8, wherein the polycrystalline silicon has doping material of a p conductivity type.

10. The memory cell as claimed in claim 9, wherein the polycrystalline silicon is p⁺-doped.

11. The memory cell as claimed in claim 7, wherein the gate region comprises a metal having a work function which is sufficiently high such that a gate current required for erasing the memory cell is kept small.

12. The memory cell as claimed in claim 11, wherein the gate region comprises a metal having a work function of at least 4.1 electronvolts.

13. A memory device comprising:
an array of fin field effect transistor memory cells, each memory cell comprising:
a semiconductor fin;
a first and a second source/drain region disposed in the semiconductor fin;
a channel region disposed in the semiconductor fin between the first and second source/drain regions;
a charge storage layer arranged at least partly over the semiconductor fin and at least partly over sidewalls of the semiconductor fin; and
a conductive gate region over at least a portion of the charge storage layer; and
control circuitry coupled to the array of fin field effect transistors, the control circuitry arranged to provide electrical potentials to the memory cell to cause electrical charge carriers to be selectively introduced into the charge storage layer of selected ones of the memory cells and to be selectively removed from he charge storage layer of selected ones of the memory cells.

14. The memory device as claimed in claim 13, wherein the transistor memory cells are arranged essentially in matrix-type fashion.

15. The memory device as claimed in claim 14, wherein memory cells arranged along a first direction have common word line regions that are coupled to the gate regions of those memory cells, the word line regions being formed from the same material as the gate regions.

16. The memory device as claimed in claim 13, wherein the memory cells are arranged in a NAND memory cell arrangement.

17. The memory device as claimed in claims 13, wherein the control circuitry is arranged to provide electrical potentials to at least one gate region and to at least one portion of the source/drain regions, so that charge carriers can selectively be introduced into the charge storage layer of at least one selected fin field effect transistor memory cell or be removed therefrom by means of Fowler-Nordheim tunneling.

18. The memory device as claimed in claim 13, further comprising at least one first bit line region and at least one second bit line region, the first source/drain region of a respective fin field effect transistor memory cell being coupled to the first bit line region and the second source/drain region of the respective fin field effect transistor memory cell being coupled to the second bit line region.

19. The memory device as claimed in claim 18, wherein the at least one first bit line region and the at least one second bit line region comprise a plurality of first and second bit line regions that are essentially arranged in a manner running along a second direction.

20. The memory device as claimed in claim 19, wherein the first and second bit line regions have a zig zag-like structure.

21. The memory device as claimed in claim 19, wherein memory cells arranged along a first direction have common word line regions that are coupled to the gate regions of those memory cells, the word line regions being formed from the same material as the gate regions, wherein the second direction is arranged obliquely with respect to the first direction.

22. The memory device as claimed in claim 19, wherein the semiconductor fins of the memory cells and word line regions are arranged in a manner running along a third direction and the first and second bit line regions are arranged in a manner running along the second direction, wherein the third direction is arranged perpendicular to the second direction.

23. The memory device as claimed in claim 18, wherein the control circuitry is arranged to provide electrical potentials to at least one word line region and to at least one portion of the first and/or of the second bit line regions, such that charge carriers can be selectively introduced into the charge storage layer of at least one selected fin field effect transistor memory cell or be removed therefrom by means of tunneling of hot charge carriers.

24. The memory device as claimed in claim 18, wherein the control circuitry is arranged to cause the storage of two bits of information by causing the introduction of charge carriers into the charge storage layer into a boundary region between the first source/drain region and the channel region and into a boundary region into the second source/drain region and the channel region of a respective fin field effect transistor memory cell.

25. The memory device as claimed in claim 18, wherein the at least one first bit line region and the at least one second bit line region are embodied as virtual ground wirings.

26. The memory device as claimed in claim 13, wherein semiconductor fins of adjacent memory cells are arranged at a distance of from 10 nm to 100 nm from one another.

27. The memory device as claimed in claim 15, further comprising an electrically insulating covering layer that covers at least one portion of the word line regions.

28. The memory device as claimed in claim 27, wherein the covering layer extends into cavities between semiconductor fins covered with the word line region.

29. A method for producing a fin field effect transistor memory cell, the method comprising:
forming a first and a second source/drain region in a semiconductor fin, a channel region being disposed between the first and second source/drain regions;
forming a charge storage layer at least partly over the semiconductor fin; and
forming a metallically conductive gate region over at least one portion of the charge storage layer;
wherein the charge storage layer is set up in such a way that electrical charge carriers can be selectively introduced into the charge storage layer or be removed therefrom by means of applying predeterminable electrical potentials to the fin field effect transistor memory cell.

30. The method as claimed in claim 29, wherein the gate region is formed from carbon material.

31. The method as claimed in claim 30, wherein the carbon material of the gate region is formed using a chemical vapor deposition method.

32. The method as claimed in claim 30, wherein methane; acetylene; and/or ethane is used for forming the carbon material.

33. The method as claimed in claim 30, wherein a substance containing doping material is supplied during the formation of the carbon material, which doping material is set up in such a way that it increases the electrical conductivity of the gate region.

34. The method as claimed in claim 30, further comprising, after the formation of the carbon material, subjecting the carbon material to a heat treatment method step.

35. The method as claimed in claim 30, wherein, during the formation of the fin field effect transistor memory cell, energy is supplied by means of an electromagnetic radiation source.

36. The method as claimed in claim 30, wherein the carbon material is firstly deposited and is then patterned using a plasma etching method in order to form the gate region.
